(19) United States
(12) Patent Application Publication
(10) Pub. No.: US 2018/0242092 A1
(43) Pub. Date: Aug. 23, 2018

(54) MEMS MICROPHONE CHIP TRIMMING METHOD, APPARATUS, MANUFACTURING METHOD AND MICROPHONE

(71) Applicant: Goertek Inc., Shandong (CN)

(72) Inventors: Quanbo Zou, Shandong (CN); Zhe Wang, Shandong (CN); Yan Loke, Shandong (CN)

(21) Appl. No.: 15/772,580

(22) PCT Filed: Nov. 3, 2015
(86) PCT No.: PCT/CN2015/093733

§ 371 Date: May 1, 2018

(51) Int. Cl. H04R 31/00; H04R 19/04

(52) U.S. Cl. CPC H04R 31/003; B81B 2201/0257; H04R 2201/003; H04R 19/04

(57) ABSTRACT

A MEMS microphone chip trimming method, apparatus, manufacturing method and microphone are disclosed herein. The method for trimming MEMS microphone chips comprises: detecting a pull-in voltage distribution of MEMS microphone chips on a wafer; providing a mask based on the pull-in voltage distribution; and trimming the MEMS microphone chips on the wafer by using the mask.

### CROSS-REFERENCE TO RELATED APPLICATIONS

This application is a National Stage of International Application No. PCT/CN2015/093733, filed on Nov. 3, 2015, which is hereby incorporated by reference in its entirety.

### BACKGROUND

### Technical Field

The present invention relates to the technical field of MEMS and in particular, to a method for trimming MEMS microphone chips, an apparatus for trimming MEMS microphone chips and a method for manufacturing MEMS microphone.

### Description of Related Art

During the manufacturing of MEMS microphones, it is desired to keep the sensitivity of the microphone as consistent as possible. A MEMS microphone comprises a MEMS microphone chip and an ASIC chip. The sensitivity of the MEMS microphone depends on the sensitivity of the MEMS microphone chip and the gain of the ASIC chip. In the prior art, the sensitivity consistency of the microphones is kept through three approaches.

In the first approach, the gains of the ASIC chips of the MEMS microphones are controlled so that the variation thereof is small, for example, in the range of +1% to −1%.

In the second approach, the MEMS microphone chips are classified into several groups, and the pull-in voltage variation of the MEMS microphone chips in a group is relatively small. The pull-in voltage Vp is inversely proportional to the sensitivity of the MEMS microphone chip. The smaller the variation range of the pull-in voltage Vp is, the smaller the variation range of the sensitivity is. For example, the variation range of the pull-in voltage can be divided into three intervals: +20% to 7%; +7% to −7%; −7% to −20%. Based on the three intervals, the MEMS microphone chips are classified into three groups. Each group is provided with one matched ASIC chip.

In the third approach, a gain adjustable ASIC chip can be used. As such, even the pull-in voltage variation range is relatively large, the sensitivity variation of the microphone can be kept in an acceptable range by adjusting the gain of the ASIC chip.

The inventors of this invention conceive that there shall be an improvement to the prior art.

### BRIEF SUMMARY

One object of this invention is to provide a new technical solution for trimming MEMS microphone chips.

According to a first aspect of the present invention, there is provided a method for trimming MEMS microphone chips, comprising: detecting a pull-in voltage distribution of MEMS microphone chips on a wafer; providing a mask based on the pull-in voltage distribution; and trimming the MEMS microphone chips on the wafer by using the mask.

Preferably, the pull-in voltages of MEMS microphone chips with pull-in voltages higher than a threshold are lowered through the trimming.

Preferably, the mask is provided to mask MEMS microphone chips with pull-in voltages lower than a threshold.

Preferably, the mask is at least one of shadow mask, paper mask and film mask.

Preferably, the mask is formed through at least one of laser drilling, mechanical drilling, milling and patterned etching.

Preferably, the MEMS microphone chips on the wafer are trimmed by using at least one of plasma etch, reactive ion etch, ion milling, inductively coupled plasma etch.

According to a second aspect of the present invention, there is provided an apparatus for trimming MEMS microphone chips, comprising: pull-in voltage obtaining unit configured to obtain a pull-in voltage distribution of MEMS microphone chips on a wafer; and mask providing unit configured to form mask data for trimming the MEMS microphone chips on the wafer based on the pull-in voltage distribution.

According to a third aspect of the present invention, there is provided a method for manufacturing a MEMS microphone, comprising: trimming MEMS microphone chips on a wafer by using the method according to the present invention; and forming MEMS microphones by using the trimmed MEMS microphone chips.

According to a fourth aspect of the present invention, there is provided a MEMS microphone, wherein the MEMS microphone is manufactured by using the method according to the present invention.

The inventors of the present invention have found that, in the prior art, the direction of trimming MEMS microphones is to adjust the ASIC chips thereof. However, the present invention trims the MEMS microphone chips per se. So, the task to be implemented by or the technical problem to be solved by the present invention has not been conceived or anticipated by a person skilled in the art and thus the present invention is a new solution.

Further features of the present invention and advantages thereof will become apparent from the following detailed description of exemplary embodiments according to the present invention with reference to the attached drawings.

### BRIEF DESCRIPTION OF THE FIGURES

The accompanying drawings, which are incorporated in and constitute a part of the specification, illustrate embodiments of the invention and, together with the description thereof, serve to explain the principles of the invention.

FIG. 1 is a block diagram showing an example of a hardware configuration of a computing system which can be used to implement the embodiments of the present invention.

FIG. 2 shows a flow chart of the method according to an embodiment of the present invention.

FIG. 3 shows a schematic diagram of an example according to an embodiment of the present invention.

FIG. 4 is a block diagram of an apparatus for trimming MEMS microphone chips according to an embodiment of the present invention.

### DESCRIPTION OF VARIOUS EMBODIMENTS

Various exemplary embodiments of the present invention will now be described in detail with reference to the drawings. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit the invention, its application, or uses.

Techniques, methods and apparatus as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus once an item is defined in one figure, it is possible that it need not be further discussed for following figures.

### <Hardware Configuration>

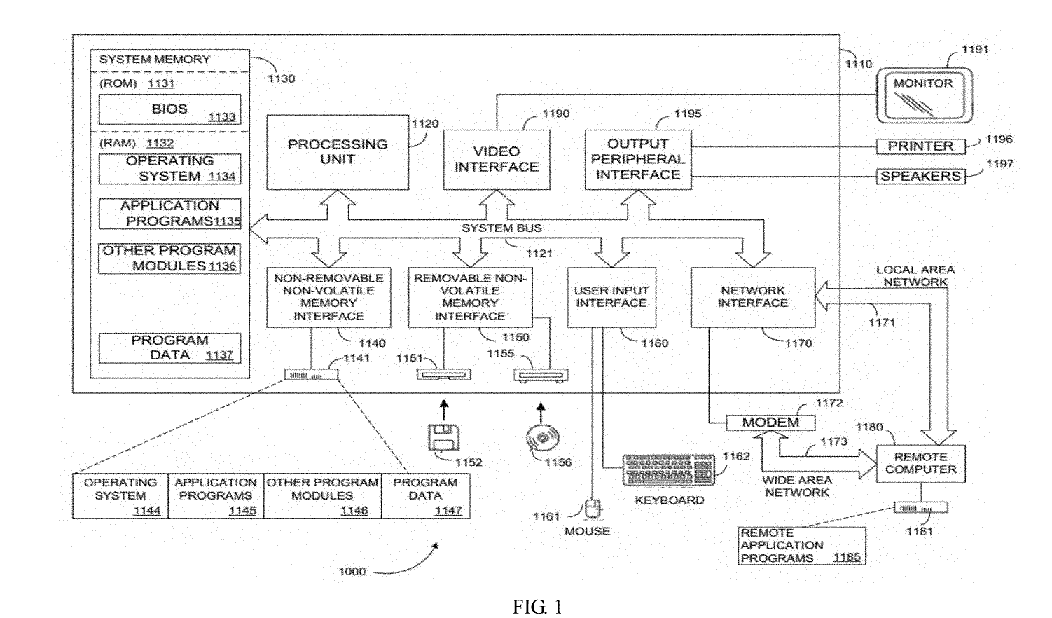

FIG. 1 is a block diagram showing an example of a hardware configuration of a computing system 1000 which can be used to implement the embodiments of the present invention.

As shown in FIG. 1, the computing system comprises a computing device 1110. The computing device 1110 comprises a processing unit 1120, a system memory 1130, non-removable non-volatile memory interface 1140, removable non-volatile memory interface 1150, user input interface 1160, network interface 1170, video interface 1190 and output peripheral interface 1195, which are connected via a system bus 1121.

The system memory 1130 comprises ROM (read-only memory) 1131 and RAM (random access memory) 1132. A BIOS (basic input output system) 1133 resides in the ROM 1131. An operating system 1134, application programs 1135, other program modules 1136 and some program data 1137 reside in the RAM 1132.

A non-removable non-volatile memory 1141, such as a hard disk, is connected to the non-removable non-volatile memory interface 1140. The non-removable non-volatile memory 1141 can store an operating system 1144, application programs 1145, other program modules 1146 and some program data 1147, for example.

Removable non-volatile memories, such as a floppy drive 1151 and a CD-ROM drive 1155, is connected to the removable non-volatile memory interface 1150. For example, a floppy disk can be inserted into the floppy drive 1151, and a CD (compact disk) can be inserted into the CD-ROM drive 1155.

Input devices, such a mouse 1161 and a keyboard 1162, are connected to the user input interface 1160.

The computing device 1110 can be connected to a remote computing device 1180 by the network interface 1170. For example, the network interface 1170 can be connected to the remote computing device 1180 via a local area network 1171. Alternatively, the network interface 1170 can be connected to a modem (modulator-demodulator) 1172, and the modem 1172 is connected to the remote computing device 1180 via a wide area network 1173.

The remote computing device 1180 may comprise a memory 1181, such as a hard disk, which stores remote application programs 1185.

The video interface 1190 is connected to a monitor 1191.

The output peripheral interface 1195 is connected to a printer 1196 and speakers 1197.

The computing system shown in FIG. 1 is merely illustrative and is in no way intended to limit the invention, its application, or uses.

When the present invention is applied into the computing system shown in FIG. 1, it can implement the technical solution of the present invention. As such, it can be deemed as a new product covered by this invention. Of course, the present invention can be fixed in a hardware directly, and the hardware per se could be a product according to the present invention.

### Embodiments and Examples

The inventors of the present invention have found that the technical solution of adjust MEMS microphones in the prior art keeps the consistency of sensitivity mainly by adjusting the gains of ASIC chips. However, the inventors of the present invention have found that the main part causing inconsistency actually lies in the MEMS microphone chips. Therefore, the inventors of this invention make improvement from a different direction and get this invention, i.e. how to make the performance of the MEMS microphone chips be consistent.

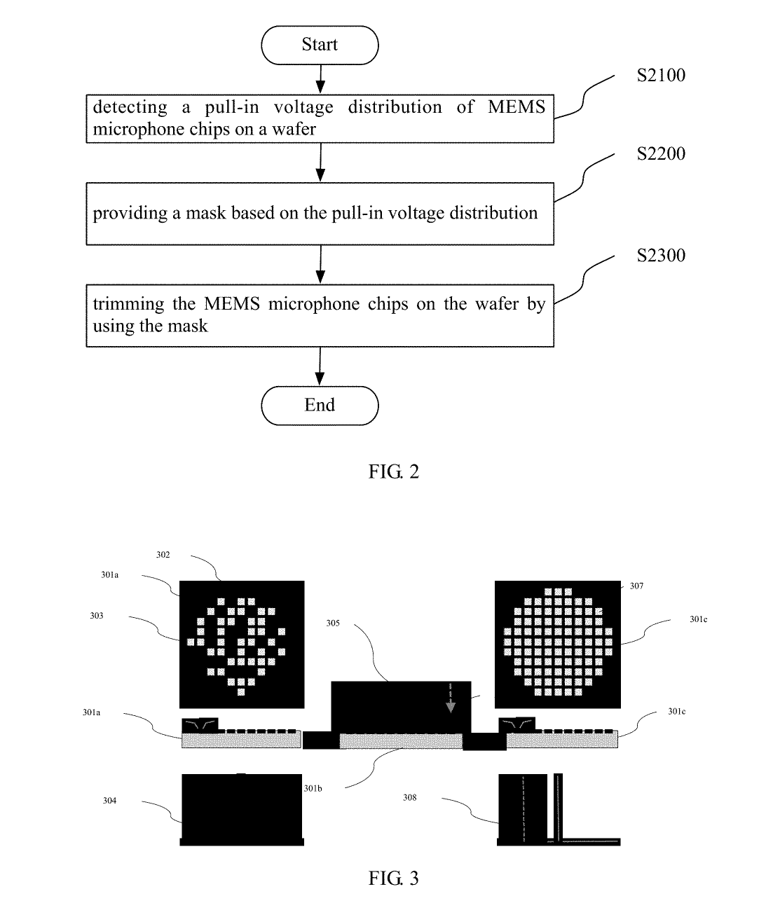

FIG. 2 shows a flow chart of the method for trimming MEMS microphone chips according to an embodiment of the present invention.

As shown in FIG. 2, at step S2100, a pull-in voltage distribution of MEMS microphone chips on a wafer is detected.

For example, the MEMS microphone chips are tested by applying voltage on the MEMS microphone chips on the wafer, to determine the pull-in voltages thereof. The pull-in voltage distribution is obtained by collecting the determined pull-in voltage.

At step S220, a mask is provided based on the pull-in voltage distribution.

For example, a threshold can be set. The threshold can be set on demand or based on experiences. For example, the MEMS microphone chips with pull-in voltages higher than the threshold will be trimmed. Thus, the mask can be set to mask the MEMS microphone chips with pull-in voltages lower than a threshold.

For example, the mask can be at least one of shadow mask, paper mask and film mask. The mask can be formed through at least one of laser drilling, mechanical drilling, milling and patterned etching.

At step S2300, the MEMS microphone chips on the wafer are trimmed by using the mask.

Through the trimming, the pull-in voltages of MEMS microphone chips with pull-in voltages higher than a threshold are lowered. In this invention, although the pull-in voltages of some MEMS microphone chips are lowered, the pull-in voltages of all MEMS microphone chips tend to be consistent.

For example, the MEMS microphone chips on the wafer can be trimmed by using at least one of plasma etch, reactive ion etch, ion milling, inductively coupled plasma etch.

FIG. 3 shows a schematic diagram of an example according to an embodiment of the present invention. FIG. 3 shows an un-trimmed MEMS microphone wafer 301a on the left side. The wafer 301a includes MEMS microphone chips 302 with relatively high pull-in voltages and MEMS microphone chips 303 with relatively low pull-in voltages. The distribution of pull-in voltage of the wafer 301a is relatively broad as indicated by 304.

As shown in the middle of FIG. 3, the MEMS microphone chips 303 on the wafer are covered by a mask 306. The wafer 301b (the wafer under trimming) is trimmed by using plasma 305, for example, to lower the pull-in voltages of the MEMS microphone chips 302. For example, the pull-in voltages can be lowered by lowering the thicknesses of the diaphragms of the MEMS microphone chips 302.

FIG. 3 shows a trimmed MEMS microphone wafer 301c on the right side. The MEMS microphone chips 307onthe wafer 301c have relatively consistent pull-in voltages, as indicated by 308.

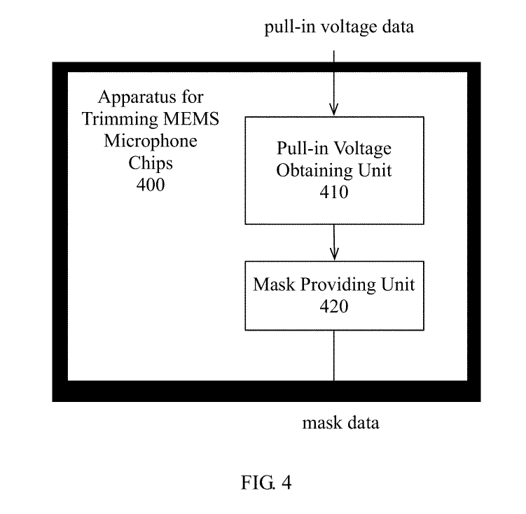

FIG. 4 is a block diagram of an apparatus for trimming MEMS microphone chips according to an embodiment of the present invention.

The apparatus 400 for trimming MEMS microphone chips comprises a pull-in voltage obtaining unit 410 and a mask providing unit 420.

The pull-in voltage obtaining unit 410 is configured to obtain a pull-in voltage distribution of MEMS microphone chips on a wafer. For example, the MEMS microphone chips on the wafer can be tested by applying voltage onto the MEMS microphone chips, to determine the pull-in voltages Vₚ thereof. The pull-in voltage obtaining unit 410 collects the determined pull-in voltage data, to obtain the pull-in voltage distribution.

The mask providing unit 420 is configured to form mask data for trimming the MEMS microphone chips on the wafer based on the pull-in voltage distribution. A mask for trimming can be formed based on the mask data output by the mask providing unit 420.

Those skilled in the art can appreciate that the pull-in voltage obtaining unit 410 and the mask providing unit 420 may be implemented in various manners. For example, a processor may be configured with instructions to implement the pull-in voltage obtaining unit 410 and the mask providing unit 420. For example, those instructions may be stored in ROM, and may be loaded from the ROM to a programmable device when the apparatus is started, to implement the pull-in voltage obtaining unit 410 and the mask providing unit 420. For example, the pull-in voltage obtaining unit 410 and the mask providing unit 420 may be solidified in a dedicated device such as an ASIC. The pull-in voltage obtaining unit 410 and the mask providing unit 420 may be two separate units or may be combined together in one implementation. The pull-in voltage obtaining unit 410 and the mask providing unit 420 can be implemented by one of the above manners or by two or more manners as above.

For example, all or part of the apparatus 400 for trimming MEMS microphone chips can be implemented by using the computing system as shown in FIG. 1.

According to another embodiment of this invention, there is provided a method for manufacturing a MEMS microphone. The manufacturing method comprises: trimming MEMS microphone chips on a wafer by using the method as above shown in FIG. 2; and forming MEMS microphones by using the trimmed MEMS microphone chips.

According to another embodiment of this invention, there is provided a MEMS microphone. The MEMS microphone is manufactured by using the above manufacturing method.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. It is well-known to a person skilled in the art that the implementations of using hardware, using software or using the combination of software and hardware can be equivalent with each other.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The scope of the present invention is defined by the attached claims.

1.-9. (canceled)

10. A method for trimming MEMS microphone chips, comprising:
detecting a pull-in voltage distribution of MEMS microphone chips on a wafer;
providing a mask based on the pull-in voltage distribution; and
trimming the MEMS microphone chips on the wafer by using the mask.

11. The method according to claim 10, wherein the pull-in voltages of MEMS microphone chips with pull-in voltages higher than a threshold are lowered through the trimming.

12. The method according to claim 10, wherein the mask is provided to mask MEMS microphone chips with pull-in voltages lower than a threshold.

13. The method according to claim 10, wherein the mask is at least one of shadow mask, paper mask and film mask.

14. The method according to claim 13, wherein the mask is formed through at least one of laser drilling, mechanical drilling, milling and patterned etching.

15. The method according to claim 10, wherein the MEMS microphone chips on the wafer are trimmed by using at least one of plasma etch, reactive ion etch, ion milling, inductively coupled plasma etch.

16. An apparatus for trimming MEMS microphone chips, comprising:
pull-in voltage obtaining unit configured to obtain a pull-in voltage distribution of MEMS microphone chips on a wafer; and
mask providing unit configured to form mask data for trimming the MEMS microphone chips on the wafer based on the pull-in voltage distribution.

17. A method for manufacturing a MEMS microphone, comprising:
trimming MEMS microphone chips on a wafer by using the method according to claim 10; and
forming MEMS microphones by using the trimmed MEMS microphone chips.

18. A MEMS microphone, wherein the MEMS microphone is manufactured by using the method according to claim 17.
